(19) United States
(12) Patent Application Publication
(10) Pub. No.: US 2019/0378793 A1
(43) Pub. Date: Dec. 12, 2019

(54) INTEGRATION OF GUARD RING WITH PASSIVE COMPONENTS

(71) Applicant: QUALCOMM Incorporated, San Diego, CA (US)

(72) Inventors: Haitao CHENG, San Diego, CA (US); Zhang JIN, San Diego, CA (US); Xinmin YU, San Diego, CA (US)

(21) Appl. No.: 16/002,378

(22) Filed: Jun. 7, 2018

(51) Int. Cl. H01L 23/522; H01L 23/58; H01L 29/94; H01L 49/02; H01L 27/06; H01L 21/74

(52) U.S. Cl. CPC H01L 23/5223; H01L 23/585; H01L 21/74; H01L 28/40; H01L 27/0629; H01L 29/94

(57) ABSTRACT

Aspects generally relate to forming components in an area inside a guard ring structure in an integrated circuit.

### BACKGROUND

### I. Field of the Disclosure

Aspects of the disclosure relate generally to guard rings, and in particular to forming components using metal layers position inside the guard ring.

### II. BACKGROUND

An integrated circuit (IC) is an electronic device that has many circuits that include active and passive components. In a typical IC the components are manufactured in and on a semiconductor substrate material.

During operation, circuits in the IC can generate electrical noise that interfere with the operation of other circuits or components in the IC. For example, in a typical digital circuit there are many signals that are switching High and Low and the switching causes electrical noise that can interfere with the operation of other circuits or components. In addition, radio frequency (RF) IC have very high frequency signals that can radiate electrical noise that can interfere with the operation of other circuits or components. Also, noise can be coupled from one circuit to other circuits through power/ground connections.

A technique to reduce interference from one circuit to another circuit or component is use of a guard ring to surround, or partially surround, a circuit or component to electrically isolate it. Guard rings help reduce interference, but the guard ring occupies area on the semiconductor substrate. There can be hundreds, or more, guard rings in a typical IC and the area of the substrate occupied by the guard rings can be significant.

There is a need for more efficient utilization of semiconductor area of an IC while still providing electrical isolation of circuits and components.

### SUMMARY OF THE DISCLOSURE

The described aspects generally relate to forming components in an area inside a guard ring structure in an integrated circuit.

In an embodiment, an integrated circuit includes a guard ring formed using several metal layers of the integrated circuit. In one embodiment, forming the guard ring using several metal layers comprising using a top metal layer and a bottom metal layer coupled together with vias. A metal-oxide-metal (MOM) capacitor structure is formed in a plurality of metal layers inside the guard ring. The MOM capacitor structure can be formed from a plurality of lateral conductive fingers using the metal layers inside the guard ring.

In another embodiment, the integrated circuit can also include a metal-oxide-silicon (MOS) capacitor structure formed inside the guard ring. The MOM capacitor structure can be coupled to the MOS capacitor structure. In another embodiment, the integrated circuit can also include a metal-insulation-metal (MIM) capacitor structure formed inside the guard ring. The MOM capacitor structure can be coupled to the MIM capacitor structure.

In another embodiment, the integrated circuit can include a metal-oxide-silicon (MOS) capacitor structure and a metal-insulation-metal (MIM) capacitor structure formed inside the guard ring. The MOM capacitor structure, the MOS capacitor structure, and the MIM capacitor structure can be coupled together.

In another embodiment an integrated circuit can include a transistor coupled to a MOM capacitor structure, the transistor configured to couple or isolate a first portion of the MOM capacitor structure to a second portion of the MOM capacitor structure.

In still another embodiment an integrated circuit can include a guard ring formed using several metal layers and a metal resistor structure formed in a plurality of metal layers inside the guard ring. The integrated circuit can also include a first transistor coupled to the metal resistor structure, the first transistor configured to enable a conductive path through the metal resistor structure or to disable the conductive path through the metal resistor structure. The integrated circuit can also include a second transistor coupled to the metal resistor structure, the second transistor configured such that when the second transistor is on the conductive path is through only a portion of the metal resistor structure and when the second transistor is off the conductive path is through the entire metal resistor structure. The integrated circuit can also include a metal strip replacing the first transistor enabling a conductive path through the metal resistor structure.

In another embodiment a method of making an integrated circuit includes forming a guard ring formed using several metal layers and forming a metal-oxide-metal (MOM) capacitor structure in a plurality of metal layers inside the guard ring. In one embodiment, forming the guard ring using several metal layers comprising using a top metal layer and a bottom metal layer coupled together with vias. The method of making the integrated circuit can also include forming a metal-oxide-silicon (MOS) capacitor structure inside the guard ring, and the MOM capacitor structure can be coupled to the MOS transistor. The method of making an integrated circuit can include forming a MIM capacitor structure inside the guard ring, and the MOM capacitor structure can be coupled to the MIM capacitor. In still another embodiment, a MOM capacitor structure, a MOS capacitor structure, and a MIM capacitor structure can be formed inside a guard ring, and the capacitor structures can be coupled together.

In another embodiment a method of making an integrated circuit includes forming a guard ring formed using several metal layers and forming a metal resistor structure in a plurality of metal layers inside the guard ring. In one embodiment, a first transistor is coupled to the metal resistor structure and configured to enable a conductive path through the metal resistor structure or to disable the conductive path through the metal resistor structure. In another embodiment a second transistor is coupled to the metal resistor structure and configured such that when the second transistor is on the conductive path is through only a portion of the metal resistor structure and when the second transistor is off the conductive path is through the entire metal resistor structure. In another embodiment, the first transistor can be replaced by a metal strip enabling a conductive path through the metal resistor structure.

Various aspect and features of the disclosure are described in further detail below.

### BRIEF DESCRIPTION OF THE FIGURES

The accompanying drawings are presented to aid in the description and illustrations of embodiments and are not intended to be limitations thereof.

FIG. 1A is a diagram illustrating a top view of typical guard ring in an IC.

FIG. 1B is a cross section of the guard ring of FIG. 1A.

FIG. 2 is a diagram illustrating a metal-oxide-metal (MOM) capacitor.

FIG. 3A is a diagram illustrating a top view of an embodiment of a guard ring and MOM capacitor combination.

FIG. 3B is a cross section view of the guard ring capacitor combination of FIG. 3A.

FIG. 4A illustrates an embodiment where a Metal-Oxide-Semiconductor (MOS) capacitor 406 is formed inside the guard ring.

FIG. 4B illustrates an embodiment where a MOM capacitor is connected in series with a MOS capacitor inside a guard ring structure.

FIG. 4C illustrates an embodiment of a Metal-Insulator-Metal (MIM) capacitor formed inside a guard ring structure.

FIG. 4D illustrates an embodiment where a MIM capacitor is connected in parallel with a MOS capacitor inside a guard ring structure.

FIG. 5A is a top view of an embodiment of a MOM capacitor formed in the area inside a guard ring.

FIG. 5B is a top view of another embodiment of a MOM capacitor formed in the area inside a guard ring.

FIG. 5C is a top view of still another embodiment of a MOM capacitor formed in the area inside a guard ring.

FIG. 6A is a top view of an embodiment of a MOM capacitor formed in the area inside a guard ring.

FIG. 6B is a top view of another embodiment of a MOM capacitor formed in the area inside a guard ring.

FIG. 6C is a top view of still another embodiment of a MOM capacitor formed inside a guard ring.

FIG. 6D is yet another embodiment of a MOM capacitor formed inside a guard ring.

FIG. 7 is an embodiment of a tunable MOM capacitor formed inside a guard ring.

FIG. 8A is an embodiment of a metal resistor formed inside a guard ring.

FIG. 8B is another embodiment of a metal resistor formed inside a guard ring.

FIG. 8C is yet another embodiment of a metal resistor formed inside a guard ring.

FIG. 9 is a flow diagram of forming a capacitor structure inside a guard ring.

FIG. 10 is a flow diagram of forming a resistor structure inside a guard ring.

The drawings may not depict all components of a particular apparatus, structure, or method. Further, like reference numerals denote like features throughout the specification and figures.

### DETAILED DESCRIPTION

Aspects disclosed in the following description and related drawings are directed to specific embodiments. Alternative embodiments may be devised without departing from the scope of the invention. Additionally, well-known elements may not be described in detail, or may be omitted, so as not to obscure relevant details. Embodiments disclosed may be suitably included in any electronic device.

With reference now to the drawing, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. Furthermore, the terminology used herein is for the purpose of describing particular embodiments and is not intended to be limiting

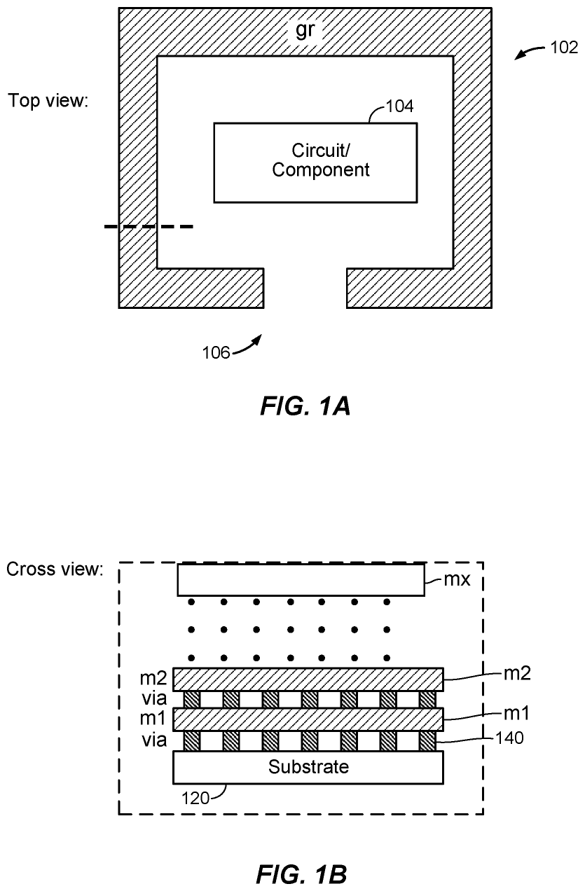

FIG. 1A is a diagram illustrating a top view of typical guard ring in an IC. FIG. 1A shows a guard ring 102 is a conductive material that surrounds a circuit or component 104 to isolate the circuit or component 104 from electrical noise from other circuits or components in the IC. In the example of FIG. 1A the guard ring 102 does not completely surround the circuit or component 104, there being a gap 106 in the guard ring. In other examples the guard ring 102 can surround the circuit or component 104 and there would not be a gap 106.

FIG. 1B is a cross section of the guard ring of FIG. 1A. FIG. 1B shows the IC includes a substrate 120, for example a silicon substrate, a plurality of metal layers M1, M2, . . . Mx. Between the substrate 120 and the first metal layer M1, and between adjacent metal layers are interlayer dielectric layers, not shown. Extending through the dielectric layer from the first metal layer M1 to the substrate, and between adjacent metal layers are a plurality of vias 140 coupling the metal layers. In the top metal layer Mx a guard ring 102 is formed using the plurality of metal layer M1, M2, . . . , Mx and vias 140.

As can be seen from FIG. 1A the guard ring 102 consumes a large area of the IC. It would be desirable to reuse the area inside the guard ring for other components, for example capacitors and resistors.

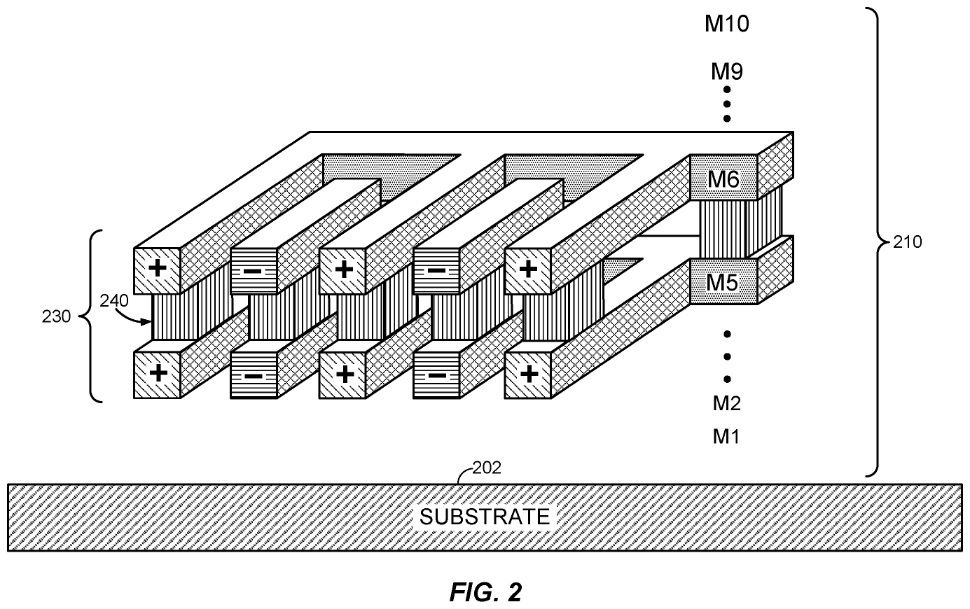

FIG. 2 is a diagram illustrating a metal-oxide-metal (MOM) capacitor. Capacitors, such as MOM capacitors are widely used in integrated circuits. As shown in FIG. 2, an interconnect stack 210 includes multiple conductive interconnect layers, or metal layers, (M1, . . . , M9, M10) over a semiconductor substrate, for example a silicon substrate, 202. In the example of FIG. 2, the MOM capacitor 230 is formed in the M5 and M6 metal layers, in other examples, the MOM capacitor can be formed using any desired number of metal layers, or separate MOM capacitors can be formed on different set of metal layers. The MOM capacitor 230 is formed from lateral conductive fingers of different polarities using the metal layers M5 and M6 of the interconnect stack 210. Dielectric layers, not shown, are provided between the conductive fingers. A plurality of conductive vias 240 couple the conductive fingers in metal layers M5 and M6 to form the plates, or fingers, of the MOM capacitor 230.

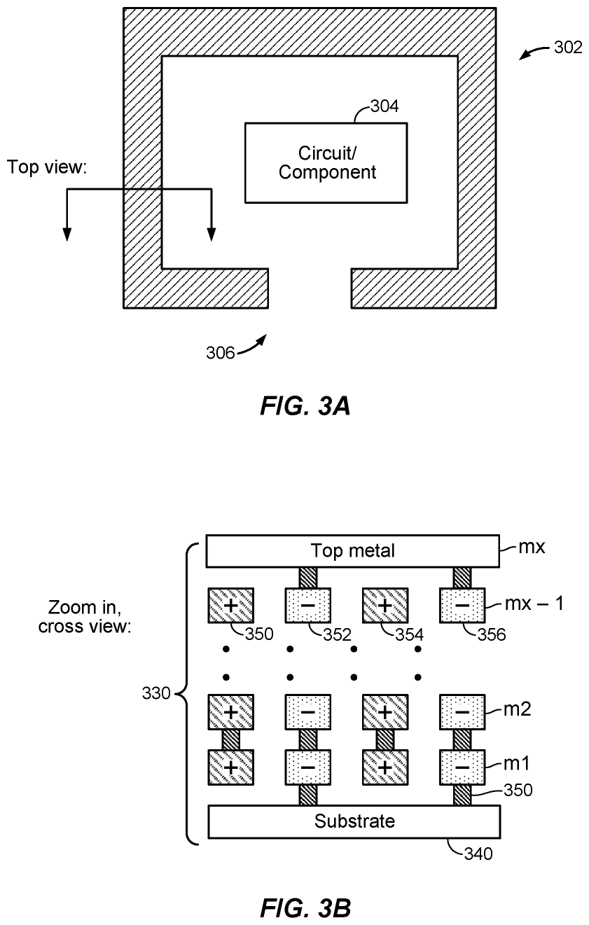

FIG. 3A is a diagram illustrating a top view of an embodiment of a guard ring and MOM capacitor combination. FIG. 3A shows a guard ring 302 that is a conductive ring, formed using several metal layers, that surrounds a circuit or component 304 to isolate the circuit or component 304 from electrical noise from other circuits or components in the IC. In the example of FIG. 3A the guard ring 302 does not completely surround the circuit or component 304, there being a gap 306 in the guard ring. In other examples the guard ring 302 can surround the circuit or component 304 and there would not be a gap 306.

FIG. 3B is a cross section view of the guard ring capacitor combination of FIG. 3A. As shown in FIG. 3B, the guard ring 302 is formed using portions (column 352 and 356) of metal layers M1-Mx. Below the top metal layer Mx there are a plurality of lower metal layers M1-M(x−1) separated by a plurality of interlayer dielectric layers, not shown. Below the bottom dielectric layer is a substrate 340. Extending through the plurality of dielectric layers are a plurality of vias 350 used to couple desired portions of metal layers M1-Mx to each other. In one example, the guard ring is formed using top metal layer MX and bottom metal layer M1 coupled together with vias. For example, a guard ring can be formed using top metal layer M1 coupled with vias to the substrate 340 using portions of metal is lateral conductive fingers 352 and 356. The other area inside the guard ring can be used to form other components.

A MOM capacitor 330 is formed from lateral conductive fingers 350, 352, 354, and 356 using the metal layers M1-Mx, in a manner similar to the description of FIG. 2. In the example of FIG. 3B, the lateral conductive fingers 350 and 354 are coupled to a high voltage, such as a supply voltage, and conductive fingers 352 and 356, forming the guard ring, are coupled to a low voltage, such as ground.

FIG. 3B illustrates using the area inside the guard ring 302 to build a MOM capacitor that can be used in the IC. Other components can also be built in the area inside a guard ring.

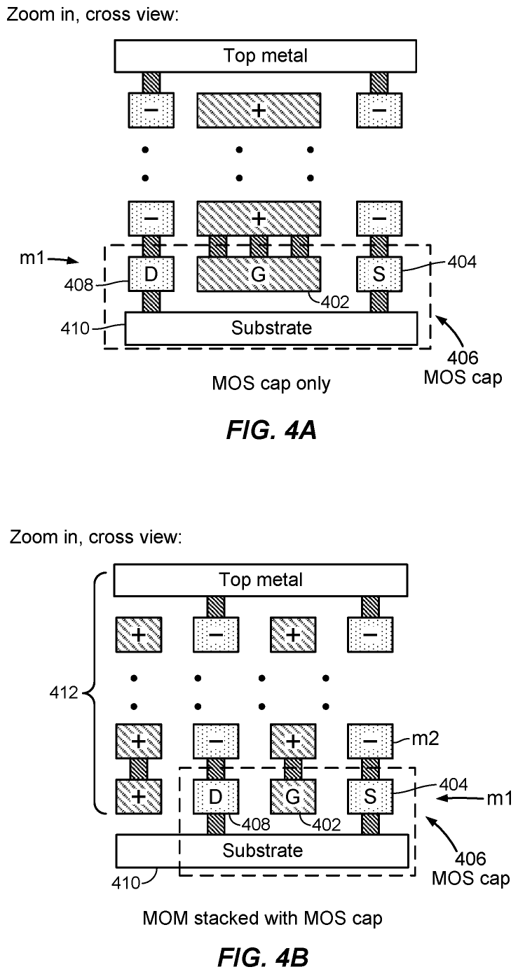

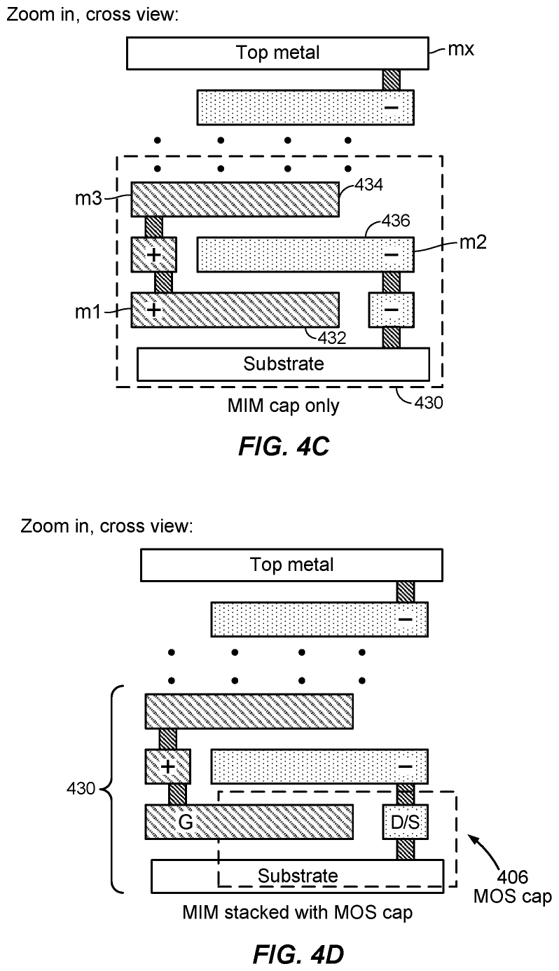

FIGS. 4A-4D illustrate various embodiments of capacitor configurations formed inside a guard ring structure. FIG. 4A illustrates an embodiment where a Metal-Oxide-Semiconductor (MOS) capacitor 406 is formed inside the guard ring. In the embodiment shown in FIG. 4A, a first portion 402 of the first metal layer M1 is coupled to a gate of a MOSFET transistor, such as a PMOS or NMOS transistor, formed in the substrate 410. As is well know in the art, the gate of a MOSFET transistor is separated by an insulator, from a channel between a source and drain of the transistor. A second and third portions 404 and 408 of the first metal layer M1 are coupled to the source and drain of the transistor, respectively. In this configuration the gate 402 forms one plate of a capacitor and the channel/source/drain form a second plate of the capacitor. In one example, the first portion 402 of the first metal layer M1 is coupled to a voltage, such as a supply voltage and the second and third portions 404 and 406 of the first metal layer M1 are coupled to a low voltage, such as ground.

FIG. 4B illustrates an embodiment where a MOM capacitor is connected with a MOS capacitor inside a guard ring structure. As shown in FIG. 4B, a MOS capacitor 406, as described with FIG. 4A is formed using the first metal layer M1. In a portion of the area inside the guard ring not occupied by the MOS capacitor 406 a MOM 412 capacitor is formed from lateral conductive fingers 420, 422, 424, and 426 using the metal layers M1-Mx, in a manner similar to the description of FIG. 2. In the example of FIG. 4B, the lateral conductive fingers 429 and 424 and the gate 402 of the MOS transistor 406 are coupled to a high voltage, such as a supply voltage, and conductive fingers 422 and 426 and the source 404 and drain 406 are coupled to a low voltage, such as ground.

FIG. 4C illustrates an embodiment of a Metal-Insulator-Metal (MIM) capacitor formed inside a guard ring structure. As shown in FIG. 4C a guard ring structure is formed using metal layers M1-Mx. A first plate of the MIM capacitor 430 is formed by coupling a portion 432 of the first metal layer M1 to a portion 434 of the third metal layer M3. A second plate of the MIM capacitor 430 is formed from a portion 436 of the second metal layer M2 located between the portion 432 of the first metal layer M1 and the portion 434 of the third metal layer M3. Additional plates of the MIM capacitor 430 can be formed in other metal layers. For example, a portion of fourth metal layer, not shown, corresponding to the portion 436 of the second metal layer M2 can be formed for another plate of the capacitor and be coupled to the second plate of the capacitor (portion 436 of the second metal layer M2). In one example, the portion 432 of the first metal layer M1 and the portion 434 of the third metal layer M3 are coupled to a high voltage, such as a supply voltage, and the portion 436 of the second metal layer M2 is coupled to a low voltage, such as ground.

FIG. 4D illustrates an embodiment where a MIM capacitor is connected in parallel with a MOS capacitor inside a guard ring structure. As shown in FIG. 4D, a MIM capacitor 430 is formed similar to FIG. 4C and MOS capacitor 406 is formed similar to FIG. 4A. The first plate of the MIM capacitor 432 is coupled to a gate of a MOSFET transistor by coupling the portion 432 of the first metal layer M1 to the gate of the MOS capacitor 306. The second plate of the MIM capacitor 430 is coupled to the source/drain of the MOSFET transistor by coupling the portion 436 of the second metal layer M2 to the source/drain contacts of the MOS capacitor 406.

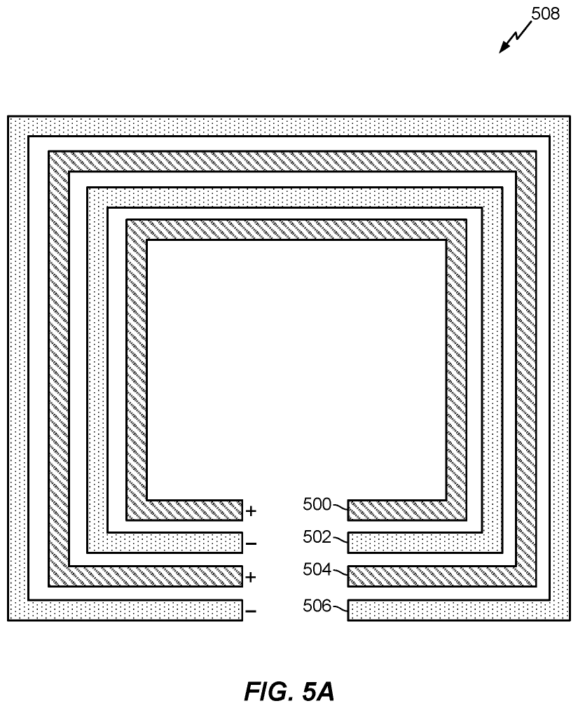

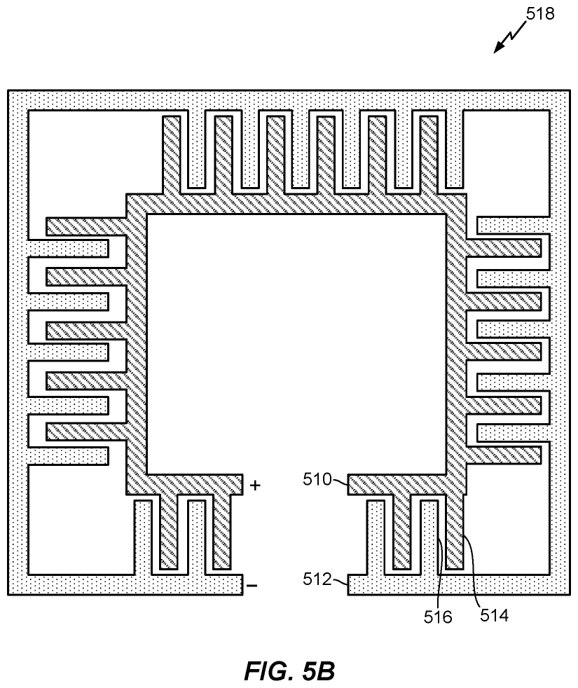

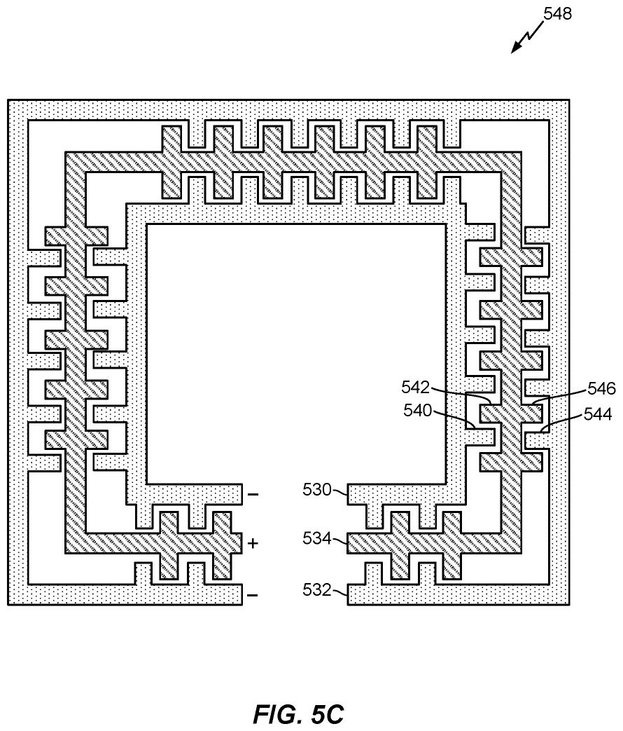

FIGS. 5A, 5B, and 5C illustrate various embodiments of MOM capacitors formed inside a guard ring. FIG. 5A is a top view of an embodiment of a MOM capacitor 508 formed in an area inside a guard ring. In FIG. 5A the top metal layer where the guard ring is formed, such as guard ring 102 illustrated in FIG. 1, is not shown. As shown in FIG. 5A, the MOM capacitor plates, formed from lateral conductive fingers, extend in a direction parallel to the direction of the guard ring. The MOM capacitor in FIG. 5A is formed by four plates, or fingers, 500, 502. 504, and 506, respectively, in concentric rings running parallel to the direction of the guard ring. In one example, the first and third plates, or fingers, 500 and 504 are coupled to a voltage, such as a supply voltage, and the second and fourth plates, or fingers, 502 and 506 are coupled to a low voltage, such as ground.

FIG. 5B is a top view of another embodiment of a MOM capacitor 518 formed in the area inside a guard ring. In FIG. 5B the top metal layer where the guard ring is formed, such as guard ring 102 illustrated in FIG. 1, is not shown. As shown in FIG. 5B, the MOM capacitor plates formed from lateral conductive fingers extend in a direction perpendicular to the direction of the guard ring. The MOM capacitor 518 in FIG. 5B is formed by an inter plate, or finger, 510 and an outer plate or finger, 512 formed as concentric rings running parallel to the inner and outer area of the guard ring respectively. Extending outward in a substantially perpendicular direction from the inner plater, or finger, 510 in a direction toward the outer plate, or finger, 512, are a plurality of first plates 514. Extending outward in a substantially perpendicular direction from the outer plater, or finger, 512 in a direction toward the inner plater, or finger, 510, are a plurality of second plates 516. The plurality of first plates 514 and plurality of second plates 516 are arranged in an interleaved manner to form opposing plates of the MOM capacitor 518. In one example, the inner plate, or finger, 510 is connected to a voltage, such as a supply voltage, and the outer plate or finger 512 is connected to a low voltage, such as ground.

FIG. 5C is a top view of still another embodiment of a MOM capacitor 548 formed in the area inside a guard ring. In FIG. 5C the top metal layer where the guard ring is formed, such as guard ring 102 illustrated in FIG. 1, is not shown. As shown in FIG. 5C, the MOM capacitor plates, formed from lateral conductive fingers, extend in a direction perpendicular to the direction of the guard ring. The MOM capacitor 548 includes an inner plate, or finger, 530, an outer plate, or finger, 532, and a middle plate, or finger, 534 as concentric rings running parallel to the direction of the guard ring. Extending outward in a substantially perpendicular direction from the inner ring 530 toward the middle ring 534 are a first plurality of plates, or fingers, 540. Extending outward in a substantially perpendicular direction from the middle ring 534 toward the inner ring 532 are a second plurality of plates, or fingers, 542. The first plurality of plates, or fingers, 540 and the second plurality of plates, or fingers, 542 are arranged in an interleaved manner to form opposing plates of the MOM capacitor 548.

Additionally, extending outward in a substantially perpendicular direction from the outer ring 532 toward the middle ring 534 are a third plurality of plates, or fingers, 544. Extending outward in a substantially perpendicular direction from the middle ring 534 toward the outer ring 532 are a fourth plurality of plates, or fingers, 546. The third plurality of plates, or fingers, 544 and the fourth plurality of plates, or fingers, 546 are arranged in an interleaved manner to form opposing plates of the MOM capacitor 548.

The arrangement of the inner ring 530 and middle ring 534 form the plates of a first MOM capacitor, and the arrangement of the outer ring 532 and middle ring 534 form the plates of a second MOM capacitor. The first and second MOM capacitors can be used individually or the inner ring 530 and outer ring 532 can be electrically coupled to form a single MOM capacitor. In one example, the middle ring 534 is coupled to a voltage, such as a supply voltage, and the inner ring 530, or outer ring 532, or both, are coupled to a low voltage, such as ground.

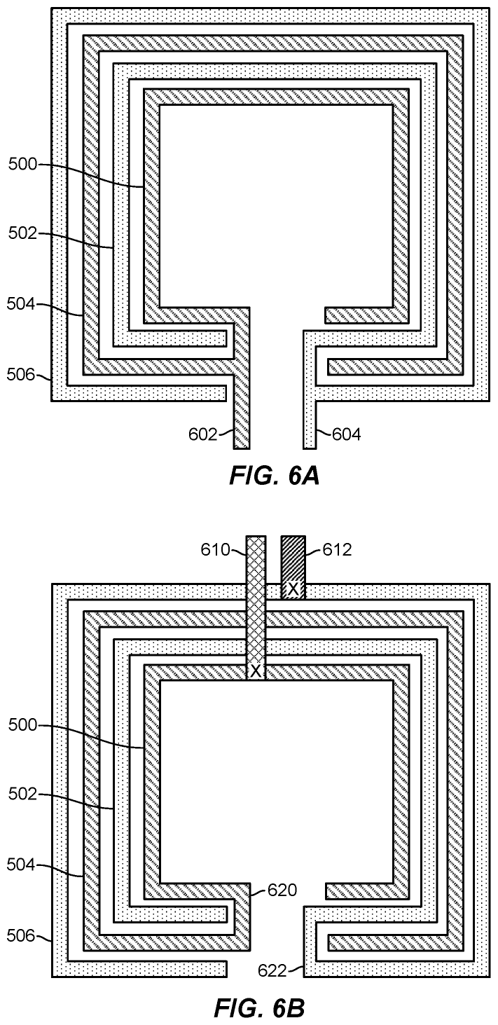

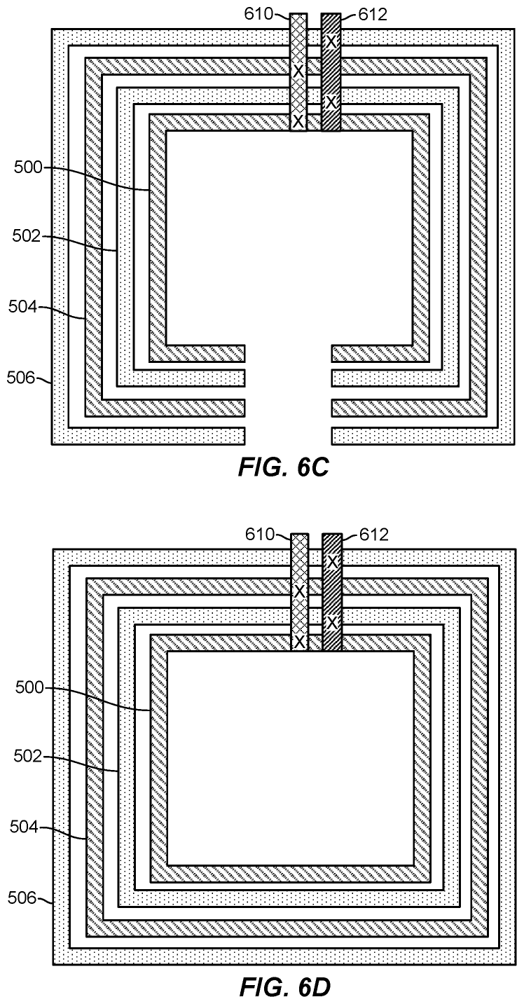

FIGS. 6A, 6B, 6C, and 6D illustrate various embodiments of making electrical connections to MOM capacitors formed inside a guard ring. FIG. 6A is a top view of an embodiment of a MOM capacitor formed in the area inside a guard ring. The MOM cap of FIG. 6A is constructed similar to the description of FIG. 5A. As shown in FIG. 6A, an electrical connection, on one of the metal layers, can be made at the ends of the open rings. In FIG. 6A the first and third rings 500 and 504 are electrically coupled by a first metal trace 602 at one end of the rings. Likewise, the second and fourth rings, 502 and 506 are electrical coupled by a second metal trace 604 at the opposite end of the open rings. In one example, the first metal trace 602 is connected to a voltage, such as a supply voltage, and the second metal trace 604 is connected to a low voltage, such as ground.

FIG. 6B is a top view of another embodiment of a MOM capacitor formed in the area inside a guard ring. The MOM cap of FIG. 6B is constructed similar to the description of FIG. 5A. As shown in FIG. 6B, an electrical connection, on one of the metal layers, can be made at any location on the rings 500, 502, 504, and 506. For example, a first metal trace 610 can make an electrical connection to the first ring 500 using vias and a second metal trace 612 can make an electrical connection to the fourth ring 506 using vias. A third metal trace 620 electrically connects the first ring 500 to the third ring 504, at one end of the of the rings, and a fourth metal trace 622 connects the second ring 502 to the fourth ring 506 at the other end of the rings. In one example, the first metal trace 610 is connected to a voltage, such as a supply voltage, and the second metal trace 612 is connected to a low voltage, such as ground.

FIG. 6C is a top view of still another embodiment of a MOM capacitor formed inside a guard ring. FIG. 6C is similar to FIG. 6B but the third metal trace 620 and fourth metal trace 622 illustrated in FIG. 6B are not used. In the example of FIG. 6C the first metal trace 610 makes electrical connection to the first ring 500 and third ring 504, and the second metal trace 612 makes electrical connection to the second ring 502 and fourth ring 506. In one example, the first metal trace 610 is connected to a voltage, such as a supply voltage, and the second metal trace 612 is connected to a low voltage, such as ground.

FIG. 6D is yet another embodiment of a MOM capacitor formed inside a guard ring. FIG. 6D is similar to FIG. 6C but the rings 500, 502, 504, and 506 form full concentric rings with no gap. In FIG. 6D the first metal trace 610 makes electrical connection to the first ring 500 and third ring 504, and the second metal trace 612 makes electrical connection to the second ring 502 and fourth ring 506. In one example, the first metal trace 610 is connected to a voltage, such as a supply voltage, and the second metal trace 612 is connected to a low voltage, such as ground.

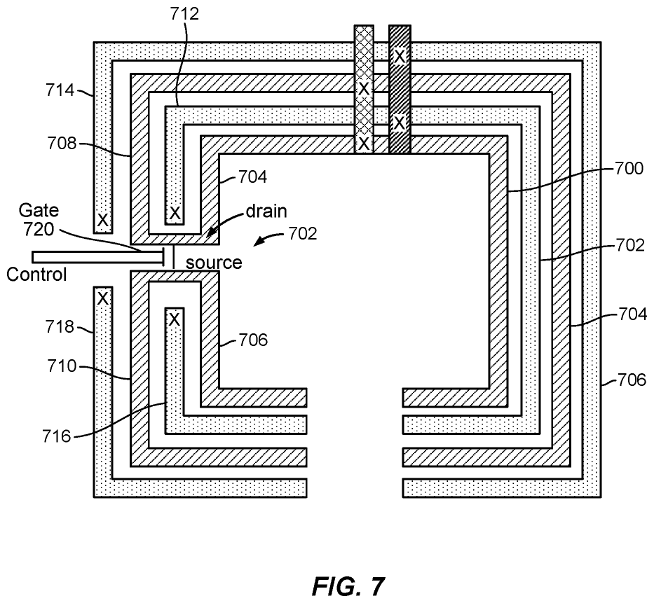

FIG. 7 is an embodiment of a tunable MOM capacitor formed inside a guard ring. FIG. 7 is similar to FIG. 6C but there is a second gap 702 in the rings 700, 702, 704, and 706. The gap 702 separating a first section 704 and a second section 706 of the first ring 700 and a first portion 708 and a second portion 710 of the third ring 704 is spanned by a transistor 720, such as a MOSFET transistor. That is, the first portion 704 of the first ring 700 and the first portion 708 of the third ring 704 are coupled to a drain of the transistor 720. The second portion 706 of the first ring 700 and the second portion 710 of the third ring 704 are coupled to a source of the transistor 720. A first portion 712 of the second ring 702 and a second portion 716 of the second ring 702 are coupled though vias to a metal layer, not shown, where they are electrically coupled. A first portion 714 of the fourth ring 706 and a second portion 718 of the fourth ring 706 are coupled though vias to a metal layer, not shown, where they are electrically coupled.

By applying a voltage to a gate of the transistor 720 the first portion 704 of the first ring 700 and the first portion 708 of the third ring 704 can be coupled to, or isolated from, the second portion 706 of the first ring 700 and the second portion 710 of the third ring 704.

By operating the transistor 720 as a switch different amounts of capacitance by be achieved. For example, if the transistor 720 is OFF, then the MOM capacitor is formed from the first portions 704, 712, 714 of the first ring 700, third ring 706, second ring 704, and fourth ring 706 respectively. If the transistor is ON the MOM capacitor is formed from the first and second portions of the four rings 700, 702, 704, and 706. When the transistor is ON the capacitance of the MOM capacitor will be higher than when the transistor 720 is OFF because the fingers forming the MOM capacitor will be longer, thereby enlarging the size of the capacitor plates. In another embodiment, there could be additional MOSFET transistors used in the guard ring structure

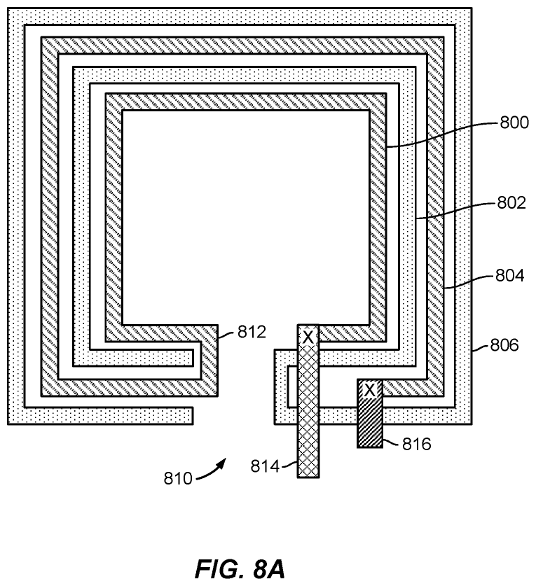

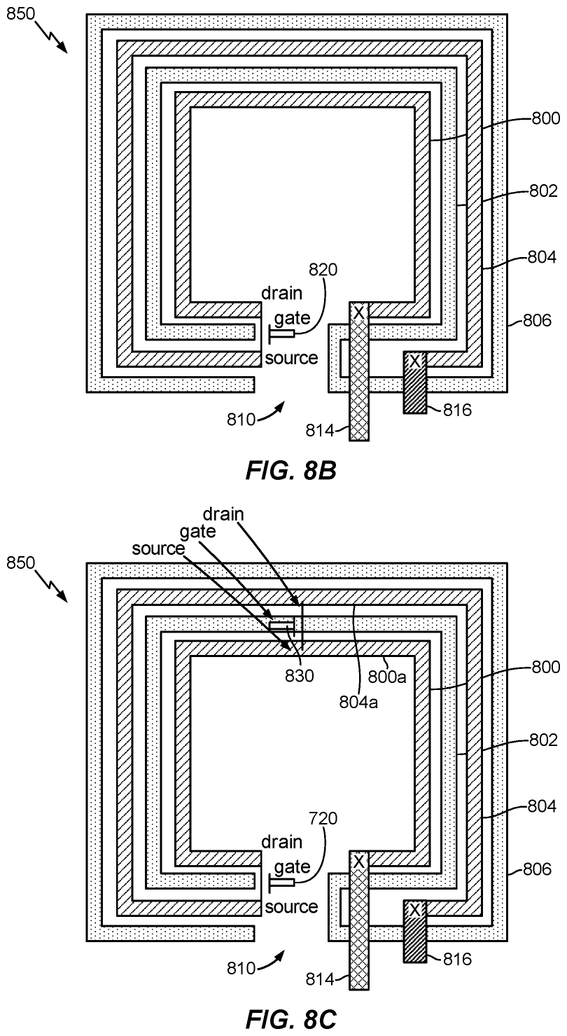

FIGS. 8A, 8B, and 8C illustrate embodiments of a metal resistor 850 formed inside a guard ring. FIGS. 8A, 8B, and 8C are top views of a metal resistor formed in the area inside a guard ring. In FIGS. 8A, 8B, and 8C the top metal layer where the guard ring is formed, such as guard ring 102 illustrated in FIG. 1, is not shown. As shown in FIGS. 8A, 8B, and 8C, the metal resistors can be formed in a single metal layer or multiple metal layers with adjacent layers coupled similar to the formation of the plates, or fingers, of the MOM capacitor described in the discussion of FIG. 3B.

FIGS. 8A, 8B, and 8C illustrate first, second, third, and fourth concentric rings 800, 802, 804, and 806, respectively, formed in a manner similar to the rings 500, 502, 504, and 506 described in FIG. 5A. The first, second, third, and fourth rings 800, 802, 804, and 806, respectively, can comprise a single metal layer, or multiple metal layers, to achieve a desired resistance. In the example of FIGS. 8A, 8B, and 8C, the first, second, third, and fourth rings 800, 802, 804, and 806, are not continuous have a gap 810.

FIG. 8A is an embodiment of a metal resistor formed inside a guard ring. In FIG. 8A, at one end of the gap 810 the first and third rings 800 and 804 are coupled with a first metal trace 812. At the other end of the gap 810 the first ring 800 is coupled to a second metal trace 814 and the third ring 804 is coupled to a third metal trace 816. The combination of the second metal trace 814, first ring 800, first metal trace 812, third ring 804 and third metal trace 816 form the metal resistor 850.

FIG. 8B is another embodiment of a metal resistor formed inside a guard ring In FIG. 8B at one end of the gap 810 the first and third rings 800 and 804 are coupled with a first transistor 820, such as a MOSFET transistor. As shown in FIG. 8B, the first ring 800 is coupled to a drain of the first transistor 820 and the third ring 804 is coupled to a source of the first transistor 820. A voltage applied to a gate of the first transistor 820 can turn the first transistor 820 ON and OFF to couple the first ring 800 to the third ring 804 or isolate the first ring 800 from the second ring 804. The combination of the second metal trace 814, first ring 800, first transistor 820, third ring 804, and third metal trace 816 form the metal resistor 850. When the first transistor 820 is ON there is a conductive path through the metal resistor 850. When the first transistor 820 is OFF there is not a conductive path through the metal resistor 750.

FIG. 8C is yet another embodiment of a metal resistor formed inside a guard ring. FIG. 8C is similar to FIG. 8B, where the first transistor 820 can couple the first ring 800 to the third ring 804 or isolate the first ring 800 from the third ring 804. In FIG. 8C there is a second transistor 830 coupled to the first ring 800 and the third ring 804 between the first transistor 820 and the second metal trace 814 and third metal trace 816. The first ring 800 is coupled to a drain of the second transistor 830 and the third ring 804 is coupled to a source of the second transistor 830. A voltage applied to a gate of the second transistor 830 can turn the second transistor 830 On and OFF to couple the first ring 800 to the third ring 804 or isolate the first ring 800 from the second ring 804. The combination of the second metal trace 814, first ring 800, first transistor 820, second transistor 830, third ring 804, and third metal trace 816 form the metal resistor 850.

The first and second transistors 820 and 830 provide flexibility in the resistance value of the metal resistor 850. For example, in one embodiment, if both the first transistor 820 and second transistor 830 are OFF, there is not a conductive path between the second metal trace 814 and the third metal trace 816, so the resistance of the metal resistor is essentially infinite. In another embodiment, if the first transistor 820 is ON and the second transistor 830 is OFF the resistance of the metal resistor 850 will be determined by the combination of the second metal trace 814, the first ring 800, the first transistor 820, the third ring 804, and third metal trace 816. In yet another embodiment, if the second transistor 830 is ON then the resistance of the metal resistor 850 will be determined by the combination of the second metal trace 814, a first portion 800A of the first ring 800, the second transistor 830, a first portion 804A of the third ring 804, and third metal trace 816 form the metal resistor 850. In this configuration, the resistance of the metal resistor 850 will be less than the previous embodiment because the conductive path is shorter, including only the first portions 800A and 804A of the first and second rings 800 and 804.

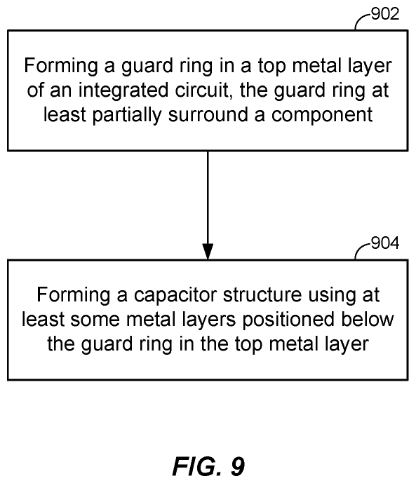

FIG. 9 is a flow diagram of forming a capacitor structure inside a guard ring. Flow begins in block 902 where a guard ring is formed using top and bottom metal layers of an integrated circuit. The guard ring at least partially surrounding a component of the integrated circuit. Flow continues to block 904 where a capacitor structure is formed using at least some of the metal layers positioned inside the guard ring.

The capacitor structure can be a metal-oxide-metal (MOM) capacitor, a metal-insulator-metal (MIM) capacitor, a metal-oxide-silicon (MOS) capacitor, or combinations of these types of capacitors. In addition, elements forming the capacitor can include transistors used to add or subtract portions of the capacitor structure to “tune” the capacitor to a desired value.

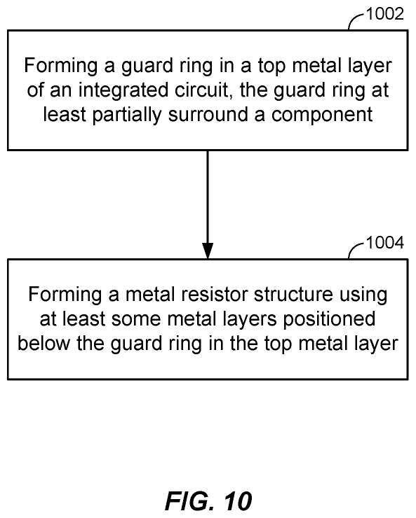

FIG. 10 is a flow diagram of forming a resistor structure inside a guard ring. Flow begins in block 1002 where a guard ring is formed using top and bottom metal layers of an integrated circuit. The guard ring at least partially surrounding a component of the integrated circuit. Flow continues to block 1004 where a resistor structure is formed using at least some of the metal layers positioned inside the guard ring.

The resistor structure can be a metal resistor. In addition, elements forming the resistor can include transistors used to add or subtract portions of the resistor structure to “tune” the resistor to a desired value.

The various illustrative logical blocks, modules, and circuits described in connection with the aspects disclosed herein may be implemented or performed in an integrated circuit (IC), a system on a chip (SoC), an Application Specific Integrated Circuit (ASIC), a Field Programmable Gate Array (FPGA) or other programmable logic device, discrete gate or transistor logic, discrete hardware components, or any combination thereof designed to perform the functions described herein.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. An integrated circuit comprising:
a guard ring formed in a first area of the integrated circuit using several metal layers, the guard ring at least partially surrounding a component in a second area of the integrated circuit;
a metal-oxide-metal (MOM) capacitor structure formed in a plurality of metal layers inside the first area.

2. The integrated circuit of claim 1, wherein forming the guard ring using several metal layers comprising using a top metal layer and a bottom metal layer coupled together with vias.

3. The integrated circuit of claim 1, wherein the MOM capacitor structure is formed from a plurality of lateral conductive fingers formed using the metal layers inside the guard ring.

4. The integrated circuit of claim 1, further comprising a metal-oxide-silicon (MOS) capacitor structure formed inside the guard ring.

5. The integrated circuit of claim 4, wherein the MOM capacitor structure is coupled to the MOS capacitor structure.

6. The integrated circuit of claim 1, further comprising a metal-insulation-metal (MIM) capacitor structure formed inside the guard ring.

7. The integrated circuit of claim 6, wherein the MOM capacitor structure is coupled to the MIM capacitor structure.

8. The integrated circuit of claim 1, further comprising a metal-oxide-silicon (MOS) capacitor structure and a metal-insulation-metal (MIM) capacitor structure formed inside the guard ring.

9. The integrated circuit of claim 8, wherein the MOM capacitor structure, the MOS capacitor structure, and the MIM capacitor structure are coupled.

10. The integrated circuit of claim 1, further comprising a transistor coupled to the MOM capacitor and configured to couple or isolate a first portion of the MOM capacitor structure to a second portion of the MOM capacitor structure.

11. The integrated circuit of claim 1, wherein the metal layers inside the guard ring are configured as a plurality of concentric rings.

12. An integrated circuit comprising:
a guard ring formed using several metal layers;
a metal resistor structure formed in a plurality of metal layers inside the guard ring.

13. The integrated circuit of claim 12, wherein forming the guard ring using several metal layers comprises using a top metal layer and a bottom metal layer coupled together with vias.

14. The integrated circuit of claim 12, further comprising a first transistor coupled to the metal resistor structure and configured to enable a conductive path through the metal resistor structure or to disable the conductive path through the metal resistor structure.

15. The integrated circuit of claim 14, further comprising a second transistor coupled to the metal resistor structure and configured such that when the second transistor is on the conductive path is through only a portion of the metal resistor structure and when the second transistor is off the conductive path is through the entire metal resistor structure.

16. The integrated circuit of claim 15, wherein the first transistor is replaced by a metal strip enabling a conductive path through the metal resistor structure.

17. A method comprising:
forming a guard ring in a first area of an integrated circuit, the guard ring formed using several metal layers, the guard ring at least partially surrounding a component in a second area of the integrated circuit; and
forming a metal-oxide-metal (MOM) capacitor structure in a plurality of metal layers in the first area.

18. The method of claim 17, wherein forming the guard ring using several metal layers comprises using a top metal layer and a bottom metal layer coupled together with vias.

19. The method of claim 17, further comprising forming a metal-oxide-silicon (MOS) capacitor structure inside the guard ring.

20. The method of claim 19, wherein the MOM capacitor structure is coupled to the MOS capacitor structure.

21. The method of claim 17, further comprising forming a metal-insulation-metal (MIM) capacitor structure inside the guard ring.

22. The method of claim 21, wherein the MOM capacitor structure is coupled to the MIM capacitor structure.

23. The method of claim 17, further comprising forming a transistor coupled to the MOM capacitor and configured to couple or isolate a first portion of the MOM capacitor structure to a second portion of the MOM capacitor structure.

24. A method comprising:
forming a guard ring formed using several metal layers; and
forming a metal resistor structure in a plurality of metal layers inside the guard ring.

25. The method of claim 24, wherein forming the guard ring using several metal layers comprises using a top metal layer and a bottom metal layer coupled together with vias.

26. The method of claim 24, further comprising forming a first transistor coupled to the metal resistor structure and configured to enable a conductive path through the metal resistor structure or to disable the conductive path through the metal resistor structure.

27. The method of claim 26, further comprising forming a second transistor coupled to the metal resistor structure and configured such that when the second transistor is on the conductive path is through only a portion of the metal resistor structure and when the second transistor is off the conductive path is through the entire metal resistor structure.

28. The method of claim 24, wherein the first transistor is replaced by a metal strip enabling a conductive path through the metal resistor structure.
